(19) United States
(12) Patent Application Publication
(10) Pub. No.: US 2021/0398595 A1
(43) Pub. Date: Dec. 23, 2021

(54) PAGE BUFFER AND SEMICONDUCTOR MEMORY DEVICE HAVING THE SAME

(71) Applicant: SK hynix Inc., Icheon-si Gyeonggi-do (KR)

(72) Inventors: Sungmook LIM, Icheon-si Gyeonggi-do (KR); Hyung Jin CHOI, Icheon-si Gyeonggi-do (KR)

(73) Assignee: SK hynix Inc., Icheon-si Gyeonggi-do (KR)

(21) Appl. No.: 17/097,720

(22) Filed: Nov. 13, 2020

(30) Foreign Application Priority Data
Jun. 18, 2020 (KR) 10-2020-0074499

(51) Int. Cl. G11C 16/24; G11C 16/04; G11C 16/26

(52) U.S. Cl. CPC G11C 16/24; G11C 16/26; G11C 16/0483

(57) ABSTRACT

The present technology relates to a page buffer and a semiconductor memory device with the same. The page buffer includes a bit line controller connected to a bit line and configured to control a potential level of a sensing node based on a current level of the bit line during a sensing operation, and a main latch configured to latch data based on a potential of the sensing node. The bit line controller includes a first transistor connected between the bit line and a common sensing node, and a second transistor connected between a power voltage terminal and the common sensing node, and the second transistor is a PMOS transistor.

### CROSS-REFERENCE TO RELATED APPLICATION

The present application claims priority under 35 U.S.C. § 119(a) to Korean patent application number 10-2020-0074499, filed on Jun. 18, 2020, in the Korean Intellectual Property Office, the entire disclosure of which is incorporated herein by reference.

### BACKGROUND

### 1. Technical Field

The present disclosure relates to an electronic device, and more particularly, to a page buffer and a semiconductor memory device including the same.

### 2. Related Art

A semiconductor memory device is a memory device that is implemented by using a semiconductor such as silicon (Si), germanium (Ge), gallium arsenide (GaAs), or indium phosphide (InP). The semiconductor memory device is largely classified as a volatile memory device or a non-volatile memory device.

Volatile memory devices are memory devices in which stored data is lost when the power supply is cut off. Examples of volatile memory devices include a static RAM (SRAM), a dynamic RAM (DRAM), a synchronous DRAM (SDRAM), and the like. Non-volatile memory devices are memory devices that maintain stored data even though the power supply is cut off. Examples of non-volatile memory devices include a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), and the like. Flash memory is largely divided into a NOR type and a NAND type.

### SUMMARY

A page buffer based on an embodiment of the present disclosure includes a bit line controller connected to a bit line and configured to control a potential level of a sensing node based on a current level of the bit line during a sensing operation, and a main latch configured to latch data based on a potential of the sensing node. The bit line controller includes a first transistor connected between the bit line and a common sensing node, and a second transistor connected between a power voltage terminal and the common sensing node, and the second transistor is a PMOS transistor.

A page buffer based on an embodiment of the present disclosure includes a bit line controller connected to a bit line and configured to control a potential level of a sensing node based on a current level of the bit line during a sensing operation, and a main latch configured to latch data based on a potential of the sensing node. The bit line controller includes a first transistor connected between the bit line and a common sensing node, and a second transistor connected between a power voltage terminal and the common sensing node, and a drain of the first transistor and a drain of the second transistor are connected to the common sensing node.

A semiconductor memory device based on an embodiment of the present disclosure includes a plurality of page buffers respectively connected to the plurality of bit lines and configured to perform a sensing operation based on a current level of the bit lines. Each of the plurality of page buffers includes a bit line controller connected to one bit line among the plurality of bit lines and configured to control a potential level of a sensing node based on the current level of the bit line during the sensing operation, and a main latch configured to latch data based on a potential of the sensing node. The bit line controller includes an NMOS transistor connected between the one bit line and a common sensing node, and a PMOS transistor connected between a power voltage terminal and the common sensing node.

A bit line controller based on an embodiment of the present disclosure includes a first transistor connected between a bit line and a common sensing node; and a second transistor connected between a power voltage terminal and the common sensing node, and wherein the second transistor is a PMOS transistor.

### BRIEF DESCRIPTION OF THE DRAWINGS

FIG. 1 is a block diagram, illustrating a memory system with a memory device, according to an embodiment of the present disclosure.

FIG. 2 is a diagram, illustrating a semiconductor memory device that is included in the memory device of FIG. 1.

FIG. 3 is a diagram, illustrating three-dimensional memory blocks.

FIG. 4 is a circuit diagram for specifically describing one of the memory blocks that is shown in FIG. 3.

FIG. 5 is a circuit diagram, illustrating memory strings that are shown in FIG. 4.

FIG. 6 is a circuit diagram, illustrating a page buffer.

FIG. 7 is a circuit diagram, illustrating a page buffer, according to an embodiment of the present disclosure.

FIG. 8 is a diagram, illustrating another embodiment of the memory system.

FIG. 9 is a diagram, illustrating another embodiment of the memory system.

FIG. 10 is a diagram, illustrating another embodiment of the memory system.

FIG. 11 is a diagram, illustrating another embodiment of the memory system.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and the descriptions are not limited to the embodiments described in the present specification or application.

Hereinafter, embodiments of the present disclosure will be described in detail with reference to the accompanying drawings, so that those skilled in the art to which the present disclosure pertains may easily carry out the technical spirit of the present disclosure.

An embodiment of the present disclosure provides a page buffer capable of improving operation performance and a semiconductor memory device including the same.

Based on the present technology, an operation performance of the page buffer may be improved by reducing variability of the sensing node.

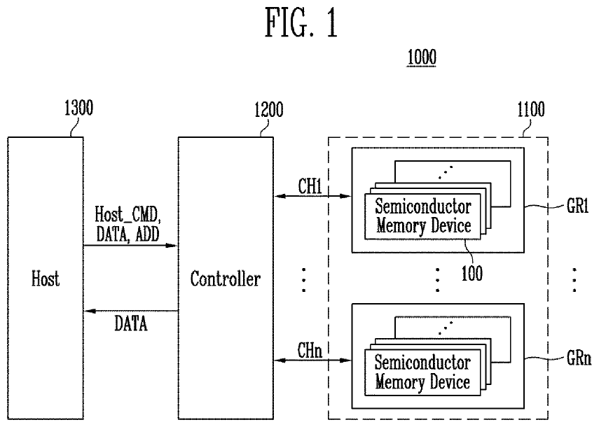

FIG. 1 is a block diagram, illustrating a memory system with a memory device based on an embodiment of the present disclosure.

Referring to FIG. 1, the memory system 1000 may include a memory device 1100, a controller 1200, and a host 1300. The memory device 1100 may include a plurality of semiconductor memory devices 100. The plurality of semiconductor memory devices 100 may be divided into a plurality of groups. Although the host 1300 is illustrated and described as being included in the memory system 1000 in the embodiment of the present disclosure, the memory system 1000 may be configured to include only the controller 1200 and the memory device 1100, and the host may be configured to be disposed outside of the memory system 1000.

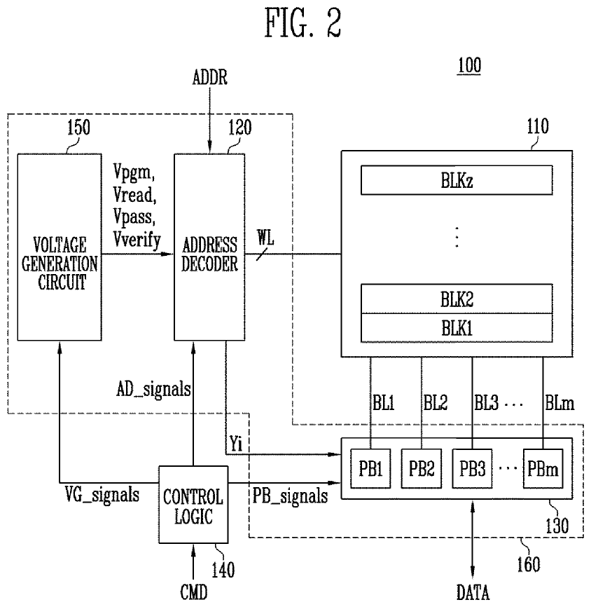

In FIG. 1, the plurality of groups GR1 to GRn of the memory device 1100 may communicate with the controller 1200 through first to n-th channels CH1 to CHn, respectively. Each semiconductor memory device 100 will be described later with reference to FIG. 2.

Each of the groups GR1 to GRn may be configured to communicate with the controller 1200 through one common channel. The controller 1200 may be configured to control the plurality of semiconductor memories 100 of the memory device 1100 through the plurality of channels CH1 to CHn.

The controller 1200 may be connected between the host 1300 and the memory device 1100. The controller 1200 may be configured to access the memory device 1100 in response to a request from the host 1300. For example, the controller 1200 may be configured to control read, program, erase, and background operations of the memory device 1100 in response to a host command Host_CMD received from the host 1300. During the program operation, the host 1300 may transmit an address ADD and data DATA to be programmed together with the host command Host_CMD, and during the read operation, the host 1300 may transmit the address ADD together with the host command Host_CMD. During the program operation, the controller 1200 may transmit a command that corresponds to the program operation and the data DATA to be programmed to the memory device 1100. During the read operation, the controller 1200 may transmit a command that corresponds to the read operation to the memory device 1100, may receive the read data DATA from the memory device 1100, and may transmit the received data DATA to the host 1300. The controller 1200 may be configured to provide an interface between the memory device 1100 and the host 1300. The controller 1200 may be configured to drive firmware to control the memory device 1100.

The host 1300 may include a portable electronic device, such as a computer, a PDA, a PMP, an MP3 player, a camera, a camcorder, or a mobile phone. The host 1300 may request a program operation, a read operation, an erase operation, or the like of the memory system 1000 through the host command Host_CMD. The host 1300 may transmit the host command Host_CMD, the data DATA, and the address ADD that correspond to the program operation to the controller 1200 for the program operation of the memory device 1100 and may transmit the host command Host_CMD and the address ADD that correspond to the read operation for the read operation to the controller 1200. At this time, the address ADD may be a logical address (logical address block) of data.

The controller 1200 and the memory device 1100 may be integrated into one semiconductor memory device. As an exemplary embodiment, the controller 1200 and the memory device 1100 may be integrated into a one semiconductor memory device to configure a memory card. For example, the controller 1200 and the memory device 1100 may be integrated into one semiconductor memory device to configure a memory card, such as a PC card (personal computer memory card international association (PCMCIA)), a compact flash card (CF), a smart media card (SM or SMC), a memory stick, a multimedia card (MMC, RS-MMC, or MMCmicro), an SD card (SD, miniSD, microSD, or SDHC), and a universal flash stage device (UFS).

In another example, the memory system 1000 is provided as one of various components of an electronic device, such as a computer, an ultra-mobile PC (UMPC), a workstation, a net-book, a personal digital assistants (PDA), a portable computer, a web tablet, a wireless phone, a mobile phone, a smart phone, an e-book, a portable multimedia player (PMP), a portable game machine, a navigation device, a black box, a digital camera, a 3-dimensional television, a digital audio recorder, a digital audio player, a digital picture recorder, a digital picture player, a digital video recorder, and a digital video player, a device capable of transmitting and receiving information in a wireless environment, one of various electronic devices configuring a home network, one of various electronic devices configuring a computer network, one of various electronic devices configuring a telematics network, an RFID device, or one of various components configuring a computing system.

As an exemplary embodiment, the memory device 1100 or memory system 1000 may be mounted as a package of various types. For example, the memory device 1100 or the memory system 1000 may be packaged and mounted through a method, such as a package on package (PoP), ball grid arrays (BGAs), chip scale packages (CSPs), plastic leaded chip carriers (PLCC), a plastic dual in line package (PDIP), a die in waffle pack, die in wafer form, a chip on board (COB), a ceramic dual in line package (CERDIP), a plastic metric quad flat pack (MQFP), a thin quad flat pack (TQFP), a small outline (SOIC), a shrink small outline package (SSOP), a thin small outline (TSOP), a system in package (SIP), a multi-chip package (MCP), a wafer-level fabricated package (WFP), or a wafer-level processed stack package (WSP).

FIG. 2 is a diagram, illustrating the semiconductor memory device that is included in the memory device of FIG. 1.

Referring to FIG. 2, the semiconductor memory device 100 may include a memory cell array 110, an address decoder 120, a read and write circuit 130, a control logic 140, and a voltage generation circuit 150. The address decoder 120, the read and write circuit 130, and the voltage generation circuit 150 may be defined as a peripheral circuit 160 that performs a read operation on the memory cell array 110.

The memory cell array 110 may include a plurality of memory blocks BLK1 to BLKz. The plurality of memory blocks BLK1 to BLKz may be connected to the address decoder 120 through word lines WL. The plurality of memory blocks BLK1 to BLKz may be connected to the read and write circuit 130 through bit lines BL1 to BLm. Each of the plurality of memory blocks BLK1 to BLKz may include a plurality of memory cells. As an embodiment, the plurality of memory cells are non-volatile memory cells. A plurality of memory cells that are connected to one word line among the plurality of memory cells may be defined as one page. That is, the memory cell array 110 may be configured of a plurality of pages.

Each of the plurality of memory blocks BLK1 to BLKz of the memory cell array 110 may include a plurality of memory strings. Each of the plurality of memory strings may include a drain select transistor that is connected in series between a bit line and a source line, a plurality of memory cells, and a source select transistor. In addition, each of the plurality of memory strings may include a pass transistor between the source select transistor and the memory cells, and between the drain select transistor and the memory cells, and may further include a pipe gate transistor between the memory cells. Detailed description of the memory cell array 110 will be described later.

The address decoder 120 may be connected to the memory cell array 110 through the word lines WL. The address decoder 120 may be configured to operate in response to address decoder control signals AD_signals that are generated in the control logic 140. The address decoder 120 may receive an address ADDR through an input/output buffer (not shown) that is inside the memory device 100.

During the program operation, the address decoder 120 may decode a row address of the received address ADDR and may apply a plurality of operation voltages, including a program voltage Vpgm, a read voltage Vread, a pass voltage Vpass, and a verify voltage Vverify that are generated by the voltage generation circuit 150 to the plurality of memory cells of the memory cell array 110 based on the decoded row address.

The address decoder 120 is configured to decode a column address of the received address ADDR. The address decoder 120 transmits a decoded column address Yi to the read and write circuit 130.

The address ADDR received during the program operation or the read operation includes a block address, the row address, and the column address. The address decoder 120 selects one memory block and one word line based on the block address and the row address. The column address may be decoded by the address decoder 120 and may be provided to the read and write circuit 130.

The address decoder 120 may include a block decoder, a row decoder, a column decoder, an address buffer, and the like.

The read and write circuit 130 may include a plurality of page buffers PB1 to PBm. The plurality of page buffers PB1 to PBm may be connected to the memory cell array 110 through the bit lines BL1 to BLm. During the read operation or the verify operation, the plurality of page buffers PB1 to PBm may perform a sensing operation that senses the program state of the memory cells that are connected to the bit lines BL1 to BLm. During the sensing operation, each of the plurality of page buffers PB1 to PBm may latch data based on a current level of the corresponding bit lines BL1 to BLm. The plurality of page buffers PB1 to PBm may perform a data transmission operation that receives and temporarily stores data to be programmed during the program operation and may adjust the potential levels of the corresponding bit lines BL1 to BLm based on the temporarily stored data.

The read and write circuit 130 may operate in response to page buffer control signals PB_signals that are output from the control logic 140.

As an exemplary embodiment, the read and write circuit 130 may include the page buffers (or page registers), a column select circuit, and the like.

The control logic 140 may be connected to the address decoder 120, the read and write circuit 130, and the voltage generation circuit 150. The control logic 140 may receive a command CMD through the input/output buffer (not shown) of the semiconductor memory device 100. The control logic 140 may be configured to control an overall operation of the semiconductor memory device 100 in response to the command CMD. For example, the control logic 140 may receive the command CMD that corresponds to the program operation. In response to the received command CMD, the control logic 140 may generate and output the address decoder control signals AD_signals to control the address decoder 120, the page buffer control signals PB_signals to control the read and write circuit 130, and voltage generation circuit control signals VG_signals to control the voltage generation circuit 150. In addition, the control logic 140 may receive the command CMD that corresponds to the read operation. In response to the received command CMD, the control logic 140 may generate and output the address decoder control signals AD_signals to control the address decoder 120, the page buffer control signals PB_signals to control the read and write circuit 130, and the voltage generation circuit control signals VG_signals to control the voltage generation circuit 150.

During the program operation, the voltage generation circuit 150 may generate the program voltage Vpgm, the pass voltage Vpass, and the verify voltage Vverify based on control of the voltage generation circuit control signals VG_signals that are output from the control logic 140, and the voltage generation circuit 150 may output the program voltage Vpgm, the pass voltage Vpass, and the verify voltage Vverify to the address decoder 120. In addition, during the read operation, the voltage generation circuit 150 may generate the read voltage Vread and the pass voltage Vpass based on the control of the voltage generation circuit control signals VG_signals that are output from the control logic 140, and the voltage generation circuit 150 may output the read voltage Vread and the pass voltage Vpass to the address decoder 120.

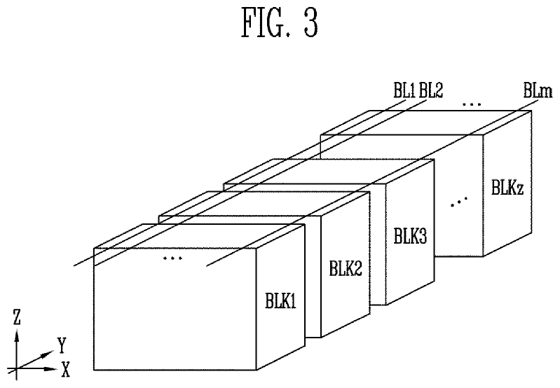

FIG. 3 is a diagram, illustrating three-dimensional memory blocks.

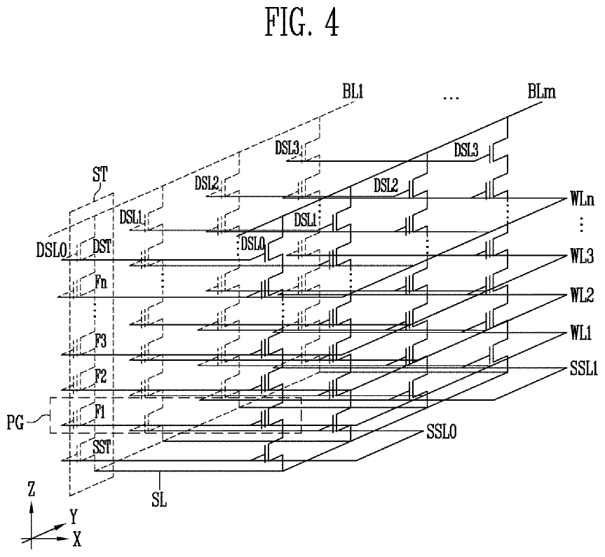

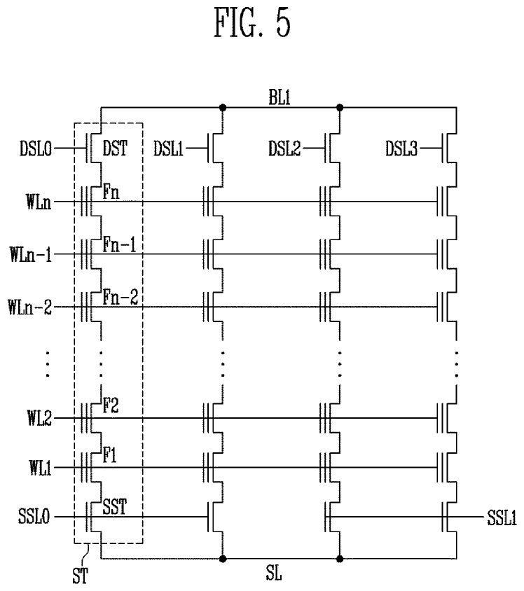

Referring to FIG. 3, the three-dimensional memory blocks BLK1 to BLKz may be arranged to be spaced apart from each other along a direction Y in which the bit lines BL1 to BLM are extended. For example, first to z-th memory blocks BLK1 to BLKz may be arranged to be spaced apart from each other along a second direction Y, and include a plurality of memory cells stacked along a third direction Z. A configuration of any one of the first to z-th memory blocks BLK1 to BLKz will be specifically described below with reference to FIGS. 4 and 5.

FIG. 4 is a circuit diagram for specifically describing one of the memory blocks shown in FIG. 3.

FIG. 5 is a circuit diagram, illustrating memory strings that are shown in FIG. 4.

Referring to FIGS. 4 and 5, each memory string ST may be connected between the bit lines BL1 to BLm and a source line SL. The memory string ST that is connected between the first bit line BL1 and the source line SL will be described as an example.

The memory string ST may include source select transistors SST that are connected in series between the source line SL and the first bit line BL1, memory cells F1 to Fn (n is a positive integer), and a drain select transistor DST. Gates of the source select transistors SST that are included in different memory strings ST, connected to different bit lines BL1 to BLm, may be connected to a first source select line SSL0 and a second source select line SSL1. For example, source select transistors that are adjacent to each other in the second direction Y among the source select transistors SST may be connected to the same source select line. For example, assuming that the source select transistors SST are sequentially arranged along the second direction Y, the gates of the source select transistors SST that are arranged in the first direction X from a first source select transistor SST and included in different strings ST and the gates of the source select transistors SST that are arranged in the first direction X from a second source select transistor SST and included in different strings ST may be connected to the first source select line SSL0. In addition, the gates of the source select transistors SST that are arranged in the first direction X from a third source select transistor SST and included in different strings ST and the gates of the source select transistors SST that are arranged in the first direction X from a fourth source select transistor SST and included in different strings ST may be connected to the second source select line SSL1.

Gates of the memory cells F1 to Fn may be connected to the word lines WL1 to WLn, and gates of the drain select transistors DST may be connected to any one of first to fourth drain select lines DSL0 to DSL3.

Gates of transistors that are arranged in the first direction X among the drain select transistors DST may be commonly connected to the same drain select line (for example, DSL0), but transistors that are arranged in the second direction Y may be connected to different drain select lines DSL1 to DSL3. For example, assuming that the drain select transistors DST are sequentially arranged along the second direction Y, the gates of the drain select transistors DST that are arranged in the first direction X from a first drain select transistor DST and included in different strings ST may be connected to a first drain select line DSL0. The drain select transistors DST that are arranged in the second direction Y from the drain select transistors DST, connected to the first drain select line DSL0, may be sequentially connected to second to fourth drain select lines DSL1 to DSL3. Therefore, the memory strings ST that are connected to a selected drain select line may be selected within a selected memory block, and memory strings ST that are connected to remaining unselected drain select lines may be unselected.

Memory cells that are connected to the same word line may form one page PG. Here, the page means a physical page. For example, among the strings ST that are connected to the first bit line BL1 to the m-th bit line BLm, a group of memory cells that is connected in the first direction X at the same word line is referred to as a page PG. For example, among the first memory cells F1 that are connected to the first word line WL1, memory cells that are arranged along the first direction X may form one page PG. Cells that are arranged in the second direction Y among the first memory cells F1, commonly connected to the first word line WL1, may be divided into different pages. Therefore, when the first drain select line DSL0 is the selected drain select line and the first word line WL1 is the selected word line, the page that is connected to the first drain select line DSL0 may become a selected page among a plurality of pages PG that are connected to the first word line WL1. The pages that are commonly connected to the first word line WL1, but connected to the unselected second to fourth drain select lines DSL1 to DSL3, may become unselected pages.

In the drawing, one source select transistor SST and one drain zo select transistor DST may be included in one string ST, but a plurality of source select transistors SST and a plurality of drain select transistors DST may be included in one string ST based on the semiconductor memory device. In addition, dummy cells may be included between the source select transistor SST, the memory cells F1 to Fn, and the drain select transistor DST based on the memory device. The dummy cells might not store user data as normal memory cells F1 to Fn would, but the dummy cells may be used to improve an electrical characteristic of each string ST. However, the dummy cells are not an important configuration in the present embodiment, and thus, detailed description thereof is omitted.

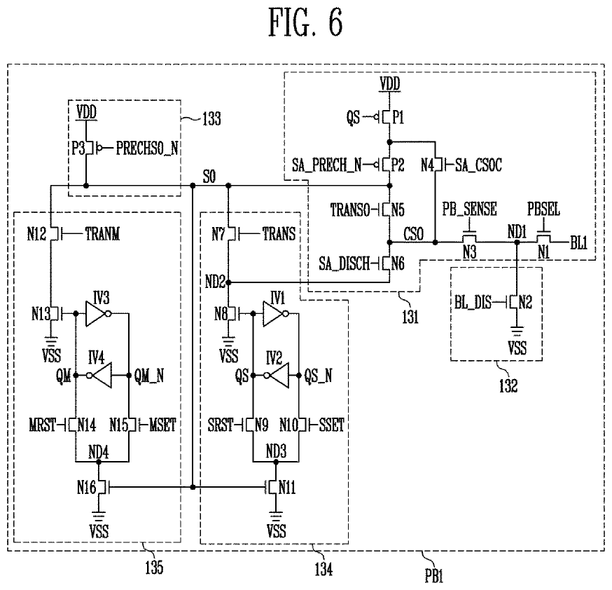

FIG. 6 is a circuit diagram, illustrating the page buffer.

Referring to FIG. 6, the page buffer PB1 may include a bit line controller 131, a bit line discharger 132, a sensing node precharger 133, a sub latch 134, and a main latch 135.

The bit line controller 131 may control a potential level of a sensing node SO based on a current level of the bit line BL1, which is changed based on a program state of the memory cell that is connected to the bit line BL1 during a sensing operation in the read operation or the verify operation.

The bit line controller 131 may include a plurality of NMOS transistors N1 and N3 to N6, and a plurality of PMOS transistors P1 and P2.

The NMOS transistor N1 may be connected between the bit line BL1 and a node ND1, and may electrically connect the bit line BL1 and the node ND1 in response to a page buffer select signal PBSEL.

The NMOS transistor N3 may be connected between the node ND1 and a common sensing node CSO, and may electrically connect the node ND1 and the common sensing node CSO in response to a page buffer sensing signal PB_SENSE.

The PMOS transistor P1 and the PMOS transistor P2 may be connected in series between a power voltage VDD and the sensing node SO, and may be turned on in response to a node QS of the sub latch 134 and a precharge signal SA_PRECH_N, respectively.

The NMOS transistor N4 may be connected between a node between the PMOS transistor P1 and the PMOS transistor P2 and the common sensing node CSO, and may supply the power voltage VDD, which is supplied through the PMOS transistor P1, to the common sensing node CSO in response to a control signal SA_CSOC.

The NMOS transistor N5 may be connected between the sensing node SO and the common sensing node CSO, and may electrically connect the sensing node SO and the common sensing node CSO in response to a transmission signal TRANSO.

The NMOS transistor N6 may be connected between the common sensing node CSO and a node ND2 of the sub latch 134, and may electrically connect the common sensing node CSO and the node ND2 in response to a discharge signal SA_DISCH.

An operation of the bit line controller 131 during the sensing operation is described as follows.

The PMOS transistor P1 and the PMOS transistor P2 may precharge the sensing node SO to a level of the power voltage VDD in response to the node QS of the sub latch 134 set to a logic low level and the precharge signal SA_PRECH_N at a logic low level.

The NMOS transistor N4 may be turned on in response to the control signal SA_CSOC, the NMOS transistor N5 may be turned on in response to the transmission signal TRANSO of a logic high level, and the common sensing node CSO may be precharged to a constant level (VDD-Vth).

Thereafter, an evaluation operation may be performed from a point in time in which the pre-charge signal SA_PRECH_N is transited to a logic high level to a point in time in which the transmission signal TRANSO is transited to a logic low level. The PMOS transistor P2 may be turned off in response to the pre-charge signal SA_PRECH_N transited to the logic high level, and the power voltage VDD that is applied to the sensing node SO may be cut off. A potential level of the sensing node SO and the common sensing node CSO may change based on the program state of the memory cell that is connected to the bit line BL1. For example, in the case of a program state in which a threshold voltage of the memory cell is greater than the read voltage or the verify voltage that is applied to the word line of the memory cell during the read or verify operation, a current might not flow through the bit line BL1. Accordingly, the potential of the common sensing node CSO and the sensing node SO may maintain a precharge level. On the other hand, in the case of an erase state in which the threshold voltage of the memory cell is less than the read voltage or the verify voltage that is applied to the word line of the memory cell during the read or verify operation, a current may flow through the bit line BL1. Accordingly, the potential of the common sensing node CSO and the sensing node SO may be decreased by a discharge level (for example, SA_CSOC-Vth) in a precharged state.

The bit line discharger 132 may be connected to the node ND1 of the bit line controller 131 to discharge a potential level of the bit line BL1.

The bit line discharger 132 may include an NMOS transistor N2 that is connected between the node ND1 and ground power VSS, and the NMOS transistor N2 may apply the ground power VSS to the node ND1 in response to a bit line discharge signal BL_DIS.

The sensing node precharger 133 may be connected between the sensing node SO and the power voltage VDD to precharge the sensing node SO to the level of the power voltage VDD.

The sensing node precharger 133 may include a PMOS transistor P3, and the PMOS transistor P3 may apply the power voltage VDD to the sensing node SO in response to a sensing node precharge signal PRECHSO_N.

The sub latch part 134 may include a plurality of NMOS transistors N7 to N11 and inverters IV1 and IV2.

The inverters IV1 and IV2 may be connected in parallel in a reverse direction between a node QS and a node QS_N to configure a latch.

The NMOS transistor N7 and the NMOS transistor N8 may be connected in series between the sensing node SO and the ground power VSS, the NMOS transistor N7 may be turned on in response to the transmission signal TRANSS, and the NMOS transistor N8 may be turned on or off based on a potential level of the node QS.

The NMOS transistor N9 may be connected between the node QS and a node ND3, and may electrically connect the node QS and the node ND3 in response to a reset signal SRST. The NMOS transistor N10 may be connected between the node QS_N and the node ND3, and may electrically connect the node QS_N and the node ND3 in response to a set signal SSET. The NMOS transistor N11 may be connected between the node ND3 and the ground power VSS, and may be turned on based on the potential of the sensing node SO to electrically connect the node ND3 and the ground power VSS. For example, in a state in which the sensing node SO is precharged to a high level, when the reset signal SRST is applied to the NMOS transistor N9 at a logic high level, the node QS and the node QS_N may be initialized to a logic low level and a logic high level, respectively. In addition, in a state in which the sensing node SO is precharged to a high level, when the set signal SSET is applied to the NMOS transistor N10 at a logic high level, the node QS and the node QS_N may be set to a logic high level and a logic low level, respectively. During a data sensing operation, the node QS may be set to a logic low level.

The main latch 135 may include a plurality of NMOS transistors N12 to N16 and inverters IV3 and IV4.

The inverters IV3 and IV4 may be connected in parallel in a reverse direction between a node QM and a node QM_N to configure a latch.

The NMOS transistor N12 and the NMOS transistor N13 may be connected in series between the sensing node SO and the ground power VSS, the NMOS transistor N12 may be turned on in response to the transmission signal TRANSM, and the NMOS transistor N13 may be turned on or off based on a potential level of the node QM.

The NMOS transistor N14 may be connected between the node QM and a node ND4, and the NMOS transistor N14 may be turned on or off in response to a reset signal MRST. The NMOS transistor N15 may be connected between the node QM_N and the node ND4 to electrically connect the node QM_N and the node ND4 in response to a set signal MSET. The NMOS transistor N16 may be connected between the node ND4 and the ground power VSS, and may connect the node ND4 and the ground power VSS based on the potential of the sensing node SO.

In the above-described bit line controller 131, the NMOS transistor N3 and the NMOS transistor N4 may be connected in a cascade form and operate in a saturation region. When the MOS transistor N4 is operated in a saturation mode of, a potential level of the control signal SA_CSOC that is applied to a gate of the MOS transistor N4 may be changed based on the potential level of the common sensing node CSO. Since the current level flowing toward the NMOS transistor N3 is fixed in the saturation mode, the current level flowing through the MOS transistor N4 may be fixed. A drain of the MOS transistor N4 may be connected to the PMOS transistor P11 to which the power voltage VDD is supplied, and a source of the MOS transistor N4 may be connected to the common sensing node CSO. In this case, when the potential level of the common sensing node CSO is changed, a voltage between the gate and source of the MOS transistor N4 may be changed by a coupling phenomenon, and the potential level of the control signal SA_CSOC that is applied to the gate of the MOS transistor N4 may be changed. Therefore, an operation characteristic of the bit line controller 131 may be reduced.

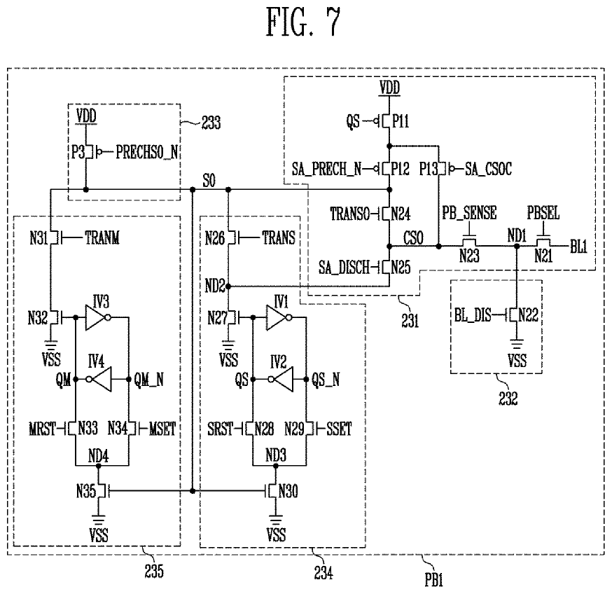

FIG. 7 is a circuit diagram, illustrating a page buffer based on an embodiment of the present disclosure.

The plurality of page buffers PB1 to PBm that are included in the read and write circuit 130 of FIG. 2 may be designed in a structure similar to each other. In an embodiment of the present disclosure, the page buffer PB1 is described as an example for convenience of description.

Referring to FIG. 7, the page buffer PB1 may include a bit line controller 231, a bit line discharger 232, a sensing node precharger 233, a sub latch 234, and a main latch 235.

The bit line controller 131 may control a potential level of a sensing node SO based on a current level of the bit line BL1, which is changed based on a program state of the memory cell that is connected to the bit line BL1 during a sensing operation in the read operation or the verify operation.

The bit line controller 231 may include a plurality of NMOS transistors N21 and N23 to N25, and a plurality of PMOS transistors P11 to P13.

The NMOS transistor N21 may be connected between the bit line BL1 and a node ND1, and may electrically connect the bit line BL1 and the node ND1 in response to a page buffer select signal PBSEL.

The NMOS transistor N23 may be connected between the node ND1 and a common sensing node CSO, and may electrically connect the node ND1 and the common sensing node CSO in response to a page buffer sensing signal PB_SENSE. The NMOS transistor N23 may be configured as an NMOS FET, may be turned off in response to the page buffer sensing signal PB_SENSE at a logic low level, and may be turned on in response to the page buffer sensing signal PB_SENSE of a logic high level. A drain of the NMOS transistor N23 may be connected to the common sensing node CSO.

The PMOS transistor P11 and the PMOS transistor P12 may be connected in series between a power voltage VDD and the sensing node SO, and may be turned on in response to a node QS of the sub latch 234 and a precharge signal SA_PRECH_N, respectively.

The PMOS transistor P13 may be connected between a node between the PMOS transistor P11 and the PMOS transistor P12 and the common sensing node CSO, and may supply the power voltage VDD, which is supplied through the PMOS transistor P11, to the common sensing node CSO in response to a control signal SA_CSOC at a logic low level. The PMOS transistor N13 may be configured as a PMOS FET, may be turned on in response to the control signal SA_CSOC at a logic low level, and may be turned off in response to the control signal SA_CSOC of a logic high level. A drain of the PMOS transistor P13 may be connected to the common sensing node CSO. The PMOS transistor P13 and the NMOS transistor N23 may be connected in a cascade form.

The NMOS transistor N24 may be connected between the sensing node SO and the common sensing node CSO, and may electrically connect the sensing node SO and the common sensing node CSO in response to a transmission signal TRANSO.

The NMOS transistor N25 may be connected between the common sensing node CSO and a node ND2 of the sub latch 234, and may electrically connect the common sensing node CSO and the node ND2 in response to a discharge signal SA_DISCH.

An operation of the bit line controller 231 during the sensing operation is described as follows.

The PMOS transistor P11 and the PMOS transistor P12 may precharge the sensing node SO to a level of the power voltage VDD in response to the node QS of the sub latch 234 set to a logic low level and the precharge signal SA_PRECH_N at a logic low level.

The PMOS transistor P13 may be turned on in response to the control signal SA_CSOC at a logic low level, the NMOS transistor N24 may be turned on in response to the transmission signal TRANSO of a logic high level, and the common sensing node CSO may be precharged to a constant level VDD.

Thereafter, an evaluation operation may be performed from a point in time in which the pre-charge signal SA_PRECH_N is transited to a logic high level to a point in time in which the transmission signal TRANSO is transited to a logic low level. The PMOS transistor P12 may be turned off in response to the pre-charge signal SA_PRECH_N transited to the logic high level, and the power voltage VDD that is applied to the sensing node SO may be cut off. A potential level of the sensing node SO and the common sensing node CSO may change based on the program state of the memory cell that is connected to the bit line BL1. For example, in the case of a program state in which a threshold voltage of the memory cell is greater than the read voltage or the verify voltage that is applied to the word line of the memory cell during the read or verify operation, a current might not flow through the bit line BL1. Accordingly, the potential of the common sensing node CSO and the sensing node SO may maintain a precharge level. On the other hand, in the case of an erase state in which the threshold voltage of the memory cell is less than the read voltage or the verify voltage applied to the word line of the memory cell during the read or verify operation, a current may flow through the bit line BL1. Accordingly, the potential of the common sensing node CSO and the sensing node SO may be decreased by a discharge level in a precharged state.

The bit line discharger 232 may be connected to the node ND1 of the bit line controller 231 to discharge a potential level of the bit line BL1.

The bit line discharger 232 may include an NMOS transistor N22 that is connected between the node ND1 and ground power VSS, and the NMOS transistor N22 may apply the ground power VSS to the node ND1 in response to a bit line discharge signal BL_DIS.

The sensing node precharger 233 may be connected between the sensing node SO and the power voltage VDD to precharge the sensing node SO to the level of the power voltage VDD.

The sensing node precharger 233 may include a PMOS transistor P3, and the PMOS transistor P3 may apply the power voltage VDD to the sensing node SO in response to a sensing node precharge signal PRECHSO_N.

The sub latch part 234 may include a plurality of NMOS transistors N26 to N30 and inverters IV1 and IV2.

The inverters IV1 and IV2 may be connected in parallel in a reverse direction between a node QS and a node QS_N to configure a latch.

The NMOS transistor N26 and the NMOS transistor N27 may be connected in series between the sensing node SO and the ground power VSS, the NMOS transistor N26 may be turned on in response to the transmission signal TRANSS, and the NMOS transistor N27 may be turned on or off based on a potential level of the node QS.

The NMOS transistor N28 may be connected between the node QS and a node ND3, and may electrically connect the node QS and the node ND3 in response to a reset signal SRST. The NMOS transistor N29 may be connected between the node QS_N and the node ND3, and may electrically connect the node QS_N and the node ND3 in response to a set signal SSET. The NMOS transistor N30 may be connected between the node ND3 and the ground power VSS, and may be turned on based on the potential of the sensing node SO to electrically connect the node ND3 and the ground power VSS. For example, in a state in which the sensing node SO is precharged to a high level, when the reset signal SRST is applied to the NMOS transistor N30 at a logic high level, the node QS and the node QS_N may be initialized to a logic low level and a logic high level, respectively. In addition, in a state in which the sensing node SO is precharged to a high level, when the set signal SSET is applied to the NMOS transistor N29 at a logic high level, the node QS and the node QS_N may be set to a logic high level and a logic low level, respectively. During a data sensing operation, the node QS may be set to a logic low level.

The main latch 235 may include a plurality of NMOS transistors N31 to N35 and inverters IV3 and IV4.

The inverters IV3 and IV4 may be connected in parallel in a reverse direction between a node QM and a node QM_N to configure a latch.

The NMOS transistor N31 and the NMOS transistor N32 may be connected in series between the sensing node SO and the ground power VSS, the NMOS transistor N31 may be turned on in response to the transmission signal TRANSM, and the NMOS transistor N32 may be turned on or off based on a potential level of the node QM.

The NMOS transistor N33 may be connected between the node QM and a node ND4, and the NMOS transistor N33 may be turned on or off in response to a reset signal MRST. The NMOS transistor N34 may be connected between the node QM_N and the node ND4 to electrically connect the node QM_N and the node ND4 in response to a set signal MSET. The NMOS transistor N35 may be connected between the node ND4 and the ground power VSS, and may connect the node ND4 and the ground power VSS based on the potential of the sensing node SO.

In the above-described bit line controller 231, when the transistor that is between the PMOS transistor P11, receiving the power voltage VDD, and the common sensing node CSO is configured as the PMOS transistor P13, the common sensing node CSO may be connected to the drain of the PMOS transistor P13. Therefore, even though the potential level of the common sensing node CSO is changed, a coupling phenomenon of the gate of the PMOS transistor P13 may be improved, and thus, an operation characteristic of the bit line controller 231 may be improved.

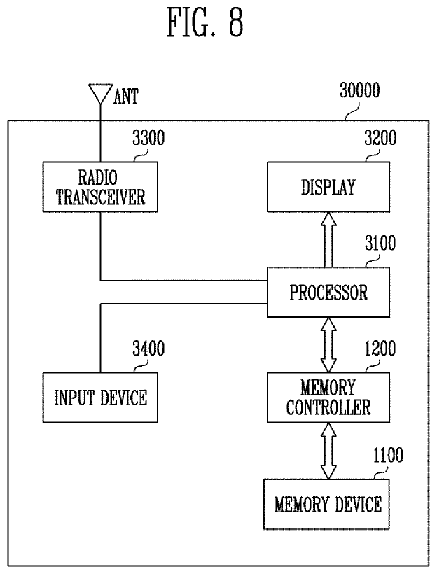

FIG. 8 is a diagram, illustrating another embodiment of the memory system.

Referring to FIG. 8, a memory system 30000 may be implemented as a cellular phone, a smart phone, a tablet PC, a personal digital assistant (PDA) or a wireless communication device. The memory system 30000 may include the memory device 1100 and the controller 1200 capable of controlling the operation of the memory device 1100. The controller 1200 may control a data access operation, for example, a program operation, an erase operation, or a read operation, of the memory device 1100 under control of a processor 3100.

Data that is programmed in the memory device 1100 may be output through a display 3200 based on the memory controller 1200.

A radio transceiver 3300 may transmit and receive a radio signal through an antenna ANT. For example, the radio transceiver 3300 may convert a radio signal that is received through the antenna ANT into a signal that may be processed by the processor 3100. Therefore, the processor 3100 may process the signal that is output from the radio transceiver 3300 and may transmit the processed signal to the memory controller 1200 or the display 3200. The memory controller 1200 may program the signal that is processed by the processor 3100 to the memory device 1100. In addition, the radio transceiver 3300 may convert a signal that is output from the processor 3100 into a radio signal and may output the converted radio signal to an external device through the antenna ANT. An input device 3400 may be a device that is capable of inputting a control signal to control the operation of the processor 3100 or data to be processed by the processor 3100. The input device 3400 may be implemented as a pointing device, such as a touch pad or a computer mouse, a keypad, or a keyboard. The processor 3100 may control an operation of the display 3200 so that data output from the controller 1200, data output from the radio transceiver 3300, or data output from the input device 3400 is output through the display 3200.

Based on an embodiment, the memory controller 1200 that is capable of controlling the operation of memory device 1100 may be implemented as a part of the processor 3100 and may also be implemented as a chip that is separate from the processor 3100. In addition, the memory controller 1200 may be implemented through the example of the controller 1200 shown in FIG. 1.

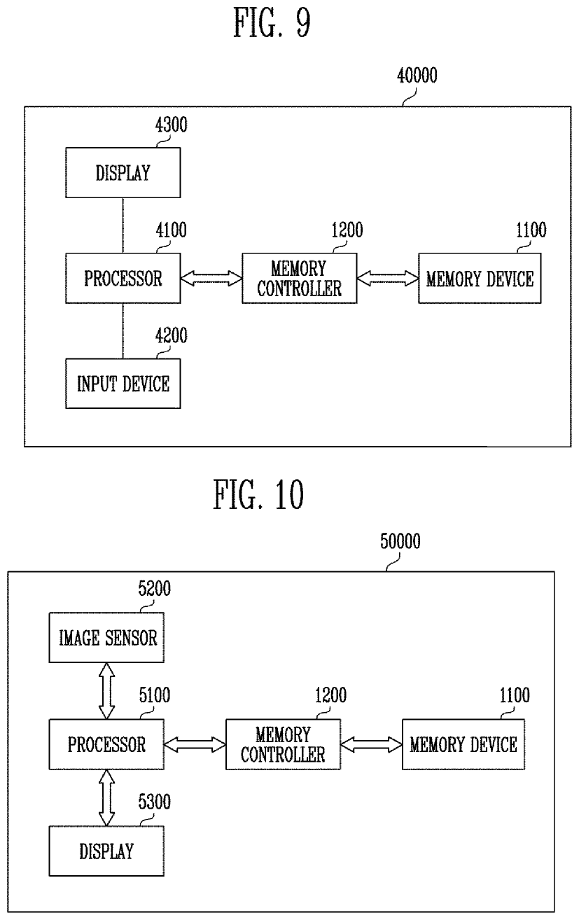

FIG. 9 is a diagram, illustrating another example of the memory system.

Referring to FIG. 9, a memory system 40000 may be implemented as a personal computer (PC), a tablet PC, a net-book, an e-reader, a personal digital assistant (PDA), a portable multimedia player (PMP), an MP3 player, or an MP4 player.

The memory system 40000 may include the memory device 1100 and the memory controller 1200, the memory controller 1200 being capable of controlling a data process operation of the storage device 1100.

A processor 4100 may output data that is stored in the memory device 1100 through a display 4300, based on data that is input through an input device 4200. For example, the input device 4200 may be implemented as a point device, such as a touch pad or a computer mouse, a keypad, or a keyboard.

The processor 4100 may control the overall operation of the memory system 40000 and control the operation of the memory controller 1200. Based on an embodiment, the memory controller 1200 that is capable of controlling the operation of memory device 1100 may be implemented as a part of the processor 4100 or may be implemented as a chip that is separate from the processor 4100. In addition, the memory controller 1200 may be implemented through the example of the controller 1200 that is shown in FIG. 1.

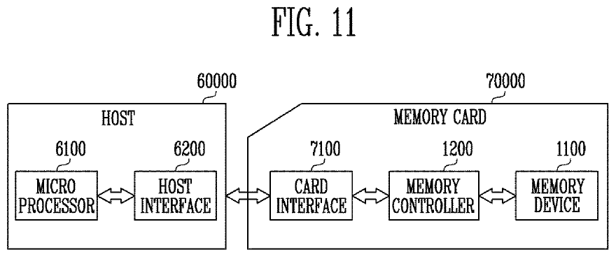

FIG. 10 is a diagram, illustrating another embodiment of the memory system.

Referring to FIG. 10, a memory system 50000 may be implemented as an image processing device, for example, a digital camera, a portable phone that is provided with a digital camera, a smart phone that is provided with a digital camera, or a tablet PC that is provided with a digital camera.

The memory system 50000 may include the memory device 1100 and the memory controller 1200 that is capable of controlling a data process operation, such as a program operation, an erase operation, or a read operation, of the memory device 1100.

An image sensor 5200 of the memory system 50000 may convert an optical image into digital signals. The converted digital signals may be transmitted to a processor 5100 or the memory controller 1200. Under control of the processor 5100, the converted digital signals may be output through a display 5300 or stored in the memory device 1100 through the controller 1200. In addition, data that is stored in the memory device 1100 may be output through the display 5300 based on the processor 5100 or the memory controller 1200.

Based on an embodiment, the memory controller 1200 that is capable of controlling the operation of memory device 1100 may be implemented as a part of the processor 5100 or may be implemented as a chip that is separate from the processor 5100. In addition, the memory controller 1200 may be implemented through the example of the controller 1200 shown in FIG. 1.

FIG. 11 is a diagram, illustrating another embodiment of the memory system.

Referring to FIG. 11, a memory system 70000 may be implemented as a memory card or a smart card. The memory system 70000 may include the memory device 1100, the memory controller 1200, and a card interface 7100.

The memory controller 1200 may control the data exchange between the memory device 1100 and the card interface 7100. Based on an embodiment, the card interface 7100 may be a secure digital (SD) card interface or a multi-media card (MMC) interface, but is not limited thereto. In addition, the memory controller 1200 may be implemented through the example of the controller 1200 that is shown in FIG. 1.

The card interface 7100 of the memory system 70000 may interface with a host 60000 to facilitate the data exchange between the host 60000 and the controller 1200 based on a protocol of the host 60000. Based on an embodiment, the card interface 7100 may support a universal serial bus (USB) protocol, and an interchip (IC)-USB protocol. Here, the card interface may refer to hardware that is capable of supporting a protocol that is used by the host 60000, software that is installed in the hardware, or a signal transmission method.

When the memory system 70000 may be connected to a host interface 6200 of the host 60000, such as a PC, a tablet PC, a digital camera, a digital audio player, a mobile phone, a console video game hardware, or a digital set-top box, the interface 6200 may perform data communication with the memory device 1100 through the card interface 7100 and the memory controller 1200 that is under the control of a microprocessor 6100.

Although the present disclosure has been described with reference to the limited embodiments and drawings, the present disclosure is not limited to the embodiments described above, and various changes and modifications may be made from the disclosed description by those skilled in the art to which the present disclosure pertains.

What is claimed is:

1. A page buffer comprising:
a bit line controller connected to a bit line and configured to control a potential level of a sensing node based on a current level of the bit line during a sensing operation; and
a main latch configured to latch data based on a potential of the sensing node,
wherein the bit line controller comprises:
a first transistor connected between the bit line and a common sensing node; and
a second transistor connected between a power voltage terminal and the common sensing node, and
wherein the second transistor is a PMOS transistor.

2. The page buffer of claim 1, wherein a drain of the second transistor are connected to the common sensing node.

3. The page buffer of claim 1, wherein the second transistor is turned on in response to a control signal at a logic low level.

4. The page buffer of claim 1, wherein the first transistor is an NMOS transistor.

5. The page buffer of claim 1, wherein the first transistor and the second transistor are connected in a cascade form.

6. A page buffer comprising:
a bit line controller connected to a bit line and configured to control a potential level of a sensing node based on a current level of the bit line during a sensing operation; and
a main latch configured to latch data based on a potential of the sensing node,
wherein the bit line controller comprises:
a first transistor connected between the bit line and a common sensing node; and
a second transistor connected between a power voltage terminal and the common sensing node, and
wherein a drain of the first transistor and a drain of the second transistor are connected to the common sensing node.

7. The page buffer of claim 6, wherein the first transistor is an NMOS transistor.

8. The page buffer of claim 6, wherein the second transistor is a PMOS transistor.

9. The page buffer of claim 6, wherein the second transistor is turned on in response to a control signal at a logic low level.

10. The page buffer of claim 6, wherein the first transistor and the second transistor are connected in a cascade form.

11. A semiconductor memory device comprising:
a memory cell array connected to a plurality of bit lines; and
a plurality of page buffers respectively connected to the plurality of bit lines and configured to perform a sensing operation based on a current level of the bit lines,
wherein each of the plurality of page buffers comprises:
a bit line controller connected to one bit line among the plurality of bit lines and configured to control a potential level of a sensing node based on the current level of the bit line during the sensing operation; and
a main latch configured to latch data based on a potential of the sensing node, and
the bit line controller comprises:
an NMOS transistor connected between the one bit line and a common sensing node; and
a PMOS transistor connected between a power voltage terminal and the common sensing node.

12. The semiconductor memory device of claim 11, wherein a drain of the PMOS transistor is connected to the common sensing node.

13. The semiconductor memory device of claim 11, wherein a drain of the NMOS transistor is connected to the common sensing node.

14. The semiconductor memory device of claim 11, wherein the PMOS transistor is turned on in response to a control signal at a logic low level.

15. The semiconductor memory device of claim 11, wherein the NMOS transistor and the PMOS transistor are connected in a cascade form.

16. A bit line controller comprising:
a first transistor connected between a bit line and a common sensing node; and
a second transistor connected between a power voltage terminal and the common sensing node, and
wherein the second transistor is a PMOS transistor.

17. The bit line controller of claim 16, wherein a drain of the first transistor and a drain of the second transistor are connected to the common sensing node.

18. The bit line controller of claim 16, wherein the second transistor is turned on in response to a control signal at a logic low level.

19. The bit line controller of claim 16, wherein the first transistor is an NMOS transistor.

20. The bit line controller of claim 16, wherein the first transistor and the second transistor are connected in a cascade form.
